(19) United States
(12) Patent Application Publication
(10) Pub. No.: US 2026/0059842 A1
(43) Pub. Date: Feb. 26, 2026

(54) SEMICONDUCTOR DEVICE INCLUDING FERROELECTRIC AND NON-FERROELECTRIC TUNNEL BARRIER LAYERS AND METHOD OF MANUFACTURING THE SAME

(71) Applicant: SK hynix Inc., Icheon-si (KR)

(72) Inventors: Won Tae KOO, Icheon-si (KR); Hwan Young KIM, Icheon-si (KR)

(21) Appl. No.: 19/018,380

(22) Filed: Jan. 13, 2025

(30) Foreign Application Priority Data
Aug. 23, 2024 (KR) 10-2024-0113880

(51) Int. Cl. H10D 64/68; H10D 30/01; H10D 30/69

(52) U.S. Cl. CPC H10D 64/689; H10D 30/0415; H10D 30/701

(57) ABSTRACT

A semiconductor device includes a first electrode layer, a first tunnel barrier layer disposed on the first electrode layer, nanoparticles disposed in the first tunnel barrier layer, a second tunnel barrier layer disposed on the first tunnel barrier layer, and a second electrode layer disposed on the second tunnel barrier layer. The first tunnel barrier layer includes a non-ferroelectric material, and the second tunnel barrier layer includes a ferroelectric material.

### CROSS-REFERENCE TO RELATED APPLICATION

The present application claims priority under 35 U.S. C § 119(a) to Korean Application No. 10-2024-0113880, filed in the Korean Intellectual Property Office on Aug. 23, 2024, the entire contents of which are incorporated herein by reference.

### BACKGROUND

### 1. Technical Field

The present disclosure generally relates to a semiconductor device including a tunnel barrier layer, and more particularly, to a semiconductor device including both a ferroelectric tunnel barrier layer and a non-ferroelectric tunnel barrier layer and method of manufacturing the same.

### 2. Related Art

In general, a ferroelectric material refers to a material having spontaneous electrical polarization in a state in which no external electric field is applied. In addition, the electrical polarization of the ferroelectric material exhibits hysteresis behavior depending on the electric field applied from the outside. Accordingly, by controlling the external electric field, the ferroelectric material can have one of different polarization states on a polarization hysteresis curve as a remanent polarization state. The ability of ferroelectric material to retain remanent polarization can be utilized to non-volatilely store signal information.

Nonvolatile memory devices are being studied in which the devices utilize ferroelectric material, ferroelectric field-effect transistors including a ferroelectric gate dielectric layer, or a ferroelectric tunnel junction device including a ferroelectric tunnel barrier layer. Ferroelectric tunnel junction devices are being studied for use in storing and reading signal information by utilizing the characteristics of a ferroelectric tunnel barrier layer when remanent polarization changes a tunneling barrier and thus changes the electrical resistance of the device.

### SUMMARY

A semiconductor device according to an embodiment of the present disclosure may include a first electrode layer, a first tunnel barrier layer disposed on the first electrode layer, nanoparticles disposed in the first tunnel barrier layer, a second tunnel barrier layer disposed on the first tunnel barrier layer, and a second electrode layer disposed on the second tunnel barrier layer. The first tunnel barrier layer includes a non-ferroelectric material, and the second tunnel barrier layer includes a ferroelectric material.

A semiconductor device according to an embodiment of the present disclosure may include a semiconductor substrate, a first tunnel barrier layer disposed on the semiconductor substrate and including a non-ferroelectric material, nanoparticles disposed in an inner region of the first tunnel barrier layer, a second tunnel barrier layer disposed on the first tunnel barrier layer and including a ferroelectric material, and an electrode layer disposed on the second tunnel barrier layer.

In a method of manufacturing a semiconductor device, a substrate may be provided. A first non-ferroelectric material layer may be formed on the substrate. Nanoparticles may be distributed on the first non-ferroelectric material layer. A second non-ferroelectric material layer covering the nanoparticles may be formed on the first non-ferroelectric material layer. A ferroelectric material layer may be formed on the second non-ferroelectric material layer. An electrode material layer may be formed on the ferroelectric material layer.

### BRIEF DESCRIPTION OF THE DRAWINGS

FIG. 1 is a schematic cross-sectional view illustrating a semiconductor device according to an embodiment of the present disclosure.

FIG. 2 is a schematic view illustrating a first writing operation of a semiconductor device according to an embodiment of the present disclosure.

FIG. 3 is a schematic view illustrating a second writing operation of a semiconductor device according to an embodiment of the present disclosure.

FIG. 4 and FIG. 5 are schematic views illustrating reading operations of a semiconductor device according to embodiments of the present disclosure.

FIG. 6 is a schematic cross-sectional view illustrating a semiconductor device according to another embodiment of the present disclosure.

FIG. 7 to FIG. 11 are schematic cross-sectional views illustrating a method of manufacturing a semiconductor device according to an embodiment of the present disclosure.

FIG. 12 to FIG. 14 are schematic cross-sectional views illustrating a method of manufacturing a semiconductor device according to another embodiment of the present disclosure.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

In performing a manufacturing method, each process constituting the manufacturing method may occur in a different order from the stated order unless the context clearly states a specific order. That is, each process may occur in the same order as the stated order, may be performed substantially simultaneously, or may be performed in the opposite order.

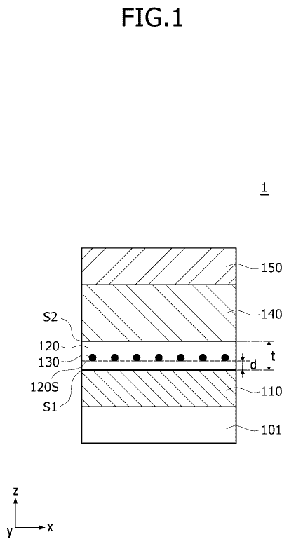

FIG. 1 is a schematic cross-sectional view illustrating a semiconductor device according to an embodiment of the present disclosure. Referring to FIG. 1, a semiconductor device 1 includes a first electrode layer 110, a first tunnel barrier layer 120 disposed on the first electrode layer 110 and including nanoparticles 130, a second tunnel barrier layer 140 disposed on the first tunnel barrier layer 120, and a second electrode layer 150 disposed on the second tunnel barrier layer 140. In addition, the semiconductor device 1 includes a substrate 101 disposed under the first electrode layer 110.

The substrate 101 is formed of various materials on which a semiconductor integration process can be performed. The substrate 101 may be, for example, a semiconductor substrate, an insulating substrate, or a conductive substrate. The substrate 101 may be, for example, a silicon (Si) substrate, a gallium arsenide (GaAs) substrate, an indium phosphide (InP) substrate, a germanium (Ge) substrate, a silicon germanium (SiGe) substrate, or a silicon-on-insulator (SOI) substrate. The substrate 101 may be, for example, a sapphire substrate, a quartz substrate, or a glass substrate. The substrate 101 may be, as another example, an N-type or P-type doped semiconductor substrate, or a conductive substrate.

The first electrode layer 110 is disposed on the substrate 101. The first electrode layer 110 includes a conductive material. The conductive material may include, for example, doped silicon (Si), platinum (Pt), ruthenium (Ru), iridium (Ir), tungsten (W), titanium (Ti), copper (Cu), aluminum (Al), tungsten nitride, titanium nitride, tantalum nitride, ruthenium oxide, iridium oxide, or a combination of two or more thereof.

In some embodiments, when the substrate 101 is a semiconductor substrate or a conductive substrate, an insulating layer (not illustrated) may be interposed between the substrate 101 and the first electrode layer 110. The insulating layer electrically insulates the substrate 101 and the first electrode layer 110 from each other.

The first tunnel barrier layer 120 is disposed on the first electrode layer 110. The first tunnel barrier layer 120 has a non-ferroelectric characteristic. A non-ferroelectric characteristic means a characteristic in which a dielectric does not have electrical polarization in a state in which an external electric field is not applied to the dielectric. That is, the first tunnel barrier layer 120 may have electrical polarization only when an external electric field is applied.

The first tunnel barrier layer 120 may exhibit a non-ferroelectric characteristic by including a non-ferroelectric material in the layer. The non-ferroelectric material may include, for example, silicon oxide, silicon nitride, silicon oxynitride, titanium oxide, tantalum oxide, aluminum oxide, zinc oxide, yttrium oxide, hafnium oxide, zirconium oxide, or a combination of two or more thereof. In a case including the hafnium oxide or the zirconium oxide, when the hafnium oxide or the zirconium oxide has a crystal structure of a monoclinic crystal system or a tetragonal crystal system, the hafnium oxide or the zirconium oxide may exhibit non-ferroelectricity. On the other hand, when the hafnium oxide or the zirconium oxide has a crystal structure of an orthorhombic system, the hafnium oxide or the zirconium oxide may exhibit ferroelectricity.

Referring to FIG. 1, the nanoparticles 130 are disposed in the first tunnel barrier layer 120. In an embodiment, the nanoparticles 130 are disposed in an inner region of the first tunnel barrier layer 120. The nanoparticles 130 are disposed to be spaced apart from a first interface S1, which is between the first electrode layer 110 and the first tunnel barrier layer 120, and a second interface S2, which is between the first tunnel barrier layer 120 and the second tunnel barrier layer 140. In an embodiment, the nanoparticles 130 are disposed on a plane 120S spaced apart from the first interface S1 by a distance d. The distance d has, for example, a magnitude of ⅓ to ⅔ of a thickness t1 of the first tunnel barrier layer 120.

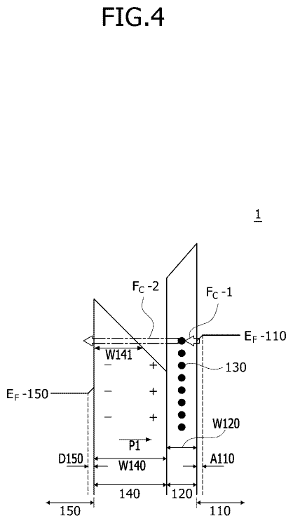

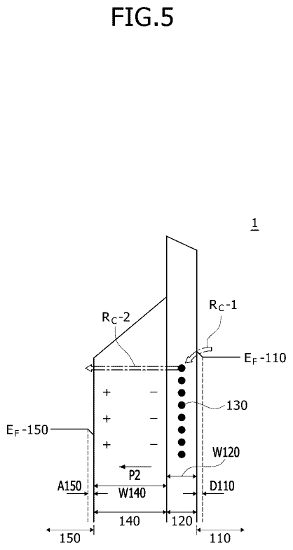

In an embodiment, the nanoparticles 130 may have forms in which metal atoms are aggregated. The nanoparticles 130 may have substantially spherical shapes. However, the shapes of the nanoparticle 130 are not necessarily limited to spherical shapes, and other three-dimensional shapes are also possible. In an embodiment, the nanoparticle 130 having spherical shapes may have diameters of, for example, 0.1 nm to 5 nm. The nanoparticle 130 may include, for example, cobalt (Co), nickel (Ni), copper (Cu), iron (Fe), platinum (Pt), gold (Au), silver (Ag), iridium (Ir), ruthenium (Ru), palladium (Pd), manganese (Mn), or a combination of two or more thereof. As described below with reference to FIG. 4 and FIG. 5, the nanoparticles 130 trap and de-trap tunneling electrons within the first tunnel barrier layer 120 during a read operation of the semiconductor device 1, thereby increasing tunneling current passing through the first tunnel barrier layer 120 and the second tunnel barrier layer 140.

Referring to FIG. 1, the second tunnel barrier layer 140 is disposed on the first tunnel barrier layer 120. The second tunnel barrier layer 140 may have a ferroelectric characteristic. A ferroelectric characteristic means a characteristic in which a dielectric has electrical polarization in a state in which an external electric field is not applied to the dielectric. That is, the second tunnel barrier layer 140 may have spontaneous electrical polarization.

The second tunnel barrier layer 140 may exhibit a ferroelectric characteristic by including a ferroelectric material in the layer. The ferroelectric material may include, for example, metal oxide having a crystal structure of an orthorhombic system. The ferroelectric material may include, for example, hafnium oxide, zirconium oxide, hafnium zirconium oxide, or a combination of two or more thereof.

In an embodiment, the second tunnel barrier layer 140 may further include a dopant doped into the ferroelectric material. The dopant may include, for example, carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), gadolinium (Gd), lanthanum (La), or a combination thereof. The dopant helps the ferroelectric material maintain an orthorhombic system crystal structure to stabilize the ferroelectric characteristics of the second tunnel barrier layer 140.

Referring to FIG. 1, the second electrode layer 150 is disposed on the second tunnel barrier layer 140. The second electrode layer 150 includes a conductive material. The conductive material may include, for example, doped silicon (Si), platinum (Pt), ruthenium (Ru), iridium (Ir), tungsten (W), titanium (Ti), copper (Cu), aluminum (Al), tungsten nitride, titanium nitride, tantalum nitride, ruthenium oxide, iridium oxide, or a combination of two or more thereof.

In an embodiment, the first electrode layer 110 and the second electrode layer 150 include different conductive materials that result in different work functions for each layer. As an example, the first electrode layer 110 includes titanium nitride (TiN) and the second electrode layer 150 includes platinum (Pt). This results in an increase in a difference in the size of an energy barrier between the first electrode layer 110 and the first tunnel barrier layer 120 and an energy barrier between the second electrode layer 150 and the second tunnel barrier layer 140, such that when performing a read operation, the tunneling current passing through the first tunnel barrier layer 120 and the second tunnel barrier layer 140 can be increased.

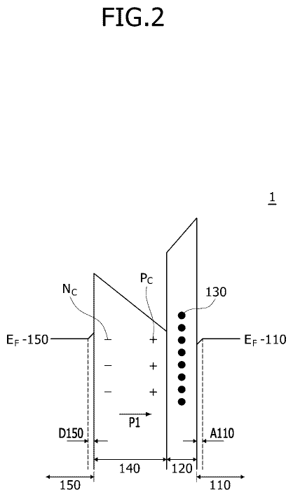

In the semiconductor device according to an embodiment of the present disclosure, as described below with reference to FIG. 2 to FIG. 5, the first electrode layer 110 may have an electron accumulation region A110 or an electron depletion region D110 in an inner region adjacent to the first tunnel barrier layer 120 depending on a remanent polarization orientation within the second tunnel barrier layer 140. Correspondingly, the second electrode layer 150 may have an electron depletion region D150 or an electron accumulation region A150 in an inner region adjacent to the second tunnel barrier layer 140.

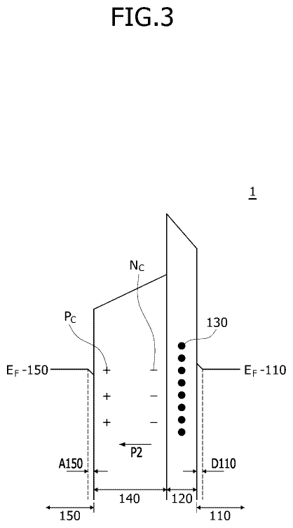

FIG. 2 is a schematic view illustrating a first writing operation of a semiconductor device according to an embodiment of the present disclosure. FIG. 3 is a schematic view illustrating a second writing operation of a semiconductor device according to an embodiment of the present disclosure. Specifically, FIG. 2 and FIG. 3 illustrate energy band diagrams of a semiconductor device in which first and second writing operations are completed, respectively. The first and second writing operations are described using a semiconductor device 1 described with reference to FIG. 1.

In an embodiment, a first writing operation is performed by applying a first writing voltage having a positive polarity to a second electrode layer 150 while a first electrode layer 110 is grounded. The first writing voltage may be a pulse voltage having an amplitude. The magnitude of the first writing voltage may be controlled by the number of times the pulse voltage is applied.

After the applied first writing voltage is removed, a second tunnel barrier layer 140 may have first remanent polarization P1, as illustrated in FIG. 2. The first remanent polarization P1 may generate positive charges Pc in an inner region of the second tunnel barrier layer 140, adjacent to a first tunnel barrier layer 120, and may generate negative charges Nc in an inner region of the second tunnel barrier layer 140, adjacent to the second electrode layer 150.

Referring to FIG. 2, the positive charges Pc and negative charges Nc generated by the first remanent polarization P1 may be partially offset or neutralized by charges arranged in the first electrode layer 110 and the second electrode layer 150, respectively. The non-offset positive charges Pc and non-offset negative charges Nc may generate a first electric field that changes the energy barriers of the energy band diagrams of the first and second electrode layers 110 and 150 and the first and second tunnel barrier layers 120 and 140. The first electric field may form an electron accumulation region A110 and an electron depletion region D150 in the first electrode layer 110 and the second electrode layer 150, respectively. As the electron accumulation region A110 is formed in the first electrode layer 110, the density of electrons that can tunnel from the first electrode layer 110 through the first tunnel barrier layer 120 and the second tunnel barrier layer 140 to the second electrode layer 150 may be increased. ‘EF-110’ and ‘EF-150’ shown in FIG. 2 refer to the Fermi energy levels of the first electrode layer 110 and the second and 150, respectively.

As described above, the first writing operation is performed such that the second tunnel barrier layer 140 has a first remanent polarization P1. As a result, the semiconductor device 1 can non-volatilely store first signal information corresponding to the first remanent polarization P1.

In an embodiment, a second writing operation is performed by applying a second writing voltage having a negative polarity to the second electrode layer 150 while the first electrode layer 110 is grounded. The second writing voltage may be a pulse voltage having an amplitude. The magnitude of the second writing voltage may be controlled by the number of times the pulse voltage is applied.

After the second writing voltage is removed, the second tunnel barrier layer 140 has second remanent polarization P2, as illustrated in FIG. 3. The second remanent polarization P2 may generate negative charges Nc in an inner region of the second tunnel barrier layer 140, adjacent to the first tunnel barrier layer 120 and positive charges Pc in an inner region of the second tunnel barrier layer 140, adjacent to the second electrode layer 150.

Referring to FIG. 3, the negative charges Nc and positive charges Pc generated by the second remanent polarization P2 may be partially offset or neutralized by the first electrode layer 110 and the second electrode layer 150. The negative charges Nc that are not offset and positive charges Pc that are not offset may generate a second electric field that changes the energy barriers as seen in the energy band diagrams. The second electric field has an opposite direction compared with the first electric field of FIG. 2. The second electric field may form an electron depletion region D110 in the first electrode layer 110 and an electron accumulation region A150 in the second electrode layer 150. As the electron depletion region D110 is formed in the first electrode layer 110, the density of electrons that can tunnel from the first electrode layer 110 through the first tunnel barrier layer 120 and the second tunnel barrier layer 140 to the second electrode layer 150 may be decreased.

As described above, the second writing operation is performed such that the second tunnel barrier layer 140 has a second remanent polarization P2. As a result, the semiconductor device 1 can non-volatilely store second signal information corresponding to the second remanent polarization P2.

FIG. 4 and FIG. 5 are schematic views illustrating reading operations of a semiconductor device according to embodiments of the present disclosure. Specifically, a reading operation of FIG. 4 may be an operation of reading out a first signal information stored by the first writing operation of FIG. 2, and a reading operation of FIG. 5 may be an operation of reading out a second signal information stored by the second writing operation of FIG. 3.

Referring to FIG. 4 and FIG. 5, reading operations of the semiconductor device 1 are performed by applying a reading voltage having a positive polarity to the second electrode layer 150 while the first electrode layer 110 is grounded. In an embodiment, the reading voltage may be a pulse voltage having an amplitude. When the reading voltage is applied, the orientations of the first remanent polarization P1 and second remanent polarization P2 of the second tunnel barrier layer 140 are not changed. That is, the magnitude of the reading voltage may be smaller than the magnitude of a coercive voltage that switches the orientations of the first remanent polarization P1 and second remanent polarization P2 of the second tunnel barrier layer 140.

Referring to FIG. 4, by the application of the reading voltage, electrons are conducted from the first electrode layer 110 through the first tunnel barrier layer 120 and the second tunnel barrier layer 140 to the second electrode layer 150. As described above, the electron accumulation region A110 may be formed in the inner region of the first electrode layer 110, adjacent to the first tunnel barrier layer 120, by the first remanent polarization P1. The density of electrons that can tunnel from the first electrode layer 110 through the first tunnel barrier layer 120 and the second tunnel barrier layer 140 to reach the second electrode layer 150 may be increased. In addition, bending of the energy band diagram occurs because of the first electric field generated by the first remanent polarization P1, and a width W141 through, which the electrons tunnel through in the second tunnel barrier layer 140, may be less than a thickness W140 of the second tunnel barrier layer 140. That is, electrons can more efficiently pass through the second tunnel barrier layer 140 with a decreased tunneling width W141 through a Fowler-Nordheim tunneling (hereinafter, referred to as “FN tunneling”). In FIG. 4, the FN tunneling process of the electrons is depicted as ‘Fc-2’. Accordingly, the density of the electrons tunneling through the second tunnel barrier layer 140 can be increased.

According to an embodiment of the present disclosure, nanoparticles 130 are disposed in the first tunnel barrier layer 120. The nanoparticles 130 function as trap sites that trap and de-trap electrons, including electrons originating from the first electrode layer 110 that pass through the first tunnel barrier layer 120. Compared to the electrons directly tunneling through the first tunnel barrier layer 120 of a thickness W120 without the influence of the nanoparticles 130, the electrons that pass through the nanoparticles 130 may more effectively pass through the first tunnel barrier layer 120. In FIG. 4, a process in which the electrons pass through the first tunnel barrier layer 120 through the nanoparticles 130 is depicted as ‘Fc-1’ and ‘Fc-2’. As a result, compared to the case in which the nanoparticles 130 are not disposed in the first tunnel barrier layer 120, the density of the electrons passing through the first tunnel barrier layer 120 may be increased.

As described, when the second tunnel barrier layer 140 has a first remanent polarization P1, the density of the electrons that tunnel from the first electrode layer 110 through the first tunnel barrier layer 120 and the second tunnel barrier layer 140 to reach the second electrode layer 150 during the reading operation can be increased. That is, in a reading operation, a high level of tunneling current corresponding to a turn-on state may be generated in the semiconductor device 1. According to an embodiment, the nanoparticles 130 disposed in the first tunnel barrier layer 120 may increase the tunneling current by performing trapping and de-trapping actions for the tunneling electrons.

Referring to FIG. 5, through the same reading method as described above, a reading voltage is applied and the density of the electrons tunneling from the first electrode layer 110 through the first tunnel barrier layer 120 and the second tunnel barrier layer 140 to reach the second electrode layer 150 may be measured.

In FIG. 5, an electron depletion region D110 may be formed in an inner region of the first electrode layer 110, adjacent to the first tunnel barrier layer 120, by the second remanent polarization P2. Accordingly, the density of the electrons that can tunnel from the first electrode layer 110 through the first tunnel barrier layer 120 and the second tunnel barrier layer 140 to reach the second electrode layer 150 decreases. In addition, when bending of the energy band diagrams occurs due to the electric field generated by the second remanent polarization P2, the width W140 through which the electrons tunnel through the second tunnel barrier layer 140 may not change. That is, the tunneling width W140 of the second tunnel barrier layer 140 may be substantially the same as the thickness W140 of the second tunnel barrier layer 140. Accordingly, electrons pass through the second tunnel barrier layer 140 through direct tunneling. In FIG. 5, the direct tunneling of the electrons is depicted as ‘Rc-2’. The tunneling efficiency of direct tunneling is lower than the tunneling efficiency of FN tunneling.

However, as described above, because the nanoparticles 130 disposed in the first tunnel barrier layer 120 function as trap sites that trap and de-trap the electrons, even when the second tunnel barrier layer 120 has second remanent polarization P2, some electrons can still pass through the first tunnel barrier layer 120 assisted by the nanoparticles 130. In FIG. 5, the process in which some electrons pass through the first tunnel barrier layer 120 through the nanoparticles 130 is depicted as ‘Rc-1’ and ‘Rc-2’. Accordingly, compared to a case in which the nanoparticles 130 are not disposed in the first tunnel barrier layer 120, the density of the electrons passing through the first tunnel barrier layer 120 may be increased.

As described, when the second tunnel barrier layer 140 has a second remanent polarization P2, the density of the electrons that tunnel from the first electrode layer 110 through the first tunnel barrier layer 120 and the second tunnel barrier layer 140 to reach the second electrode layer 150 during the reading operation may be decreased compared to the operation illustrated in FIG. 4. That is, during a reading operation, a tunneling current of a leakage current level corresponding to a turn-off state may be generated in the semiconductor device 1. However, due to electronic conduction through the nanoparticle 130 as shown FIG. 5, the tunneling current in the turn-off state according to an embodiment is greater than the tunneling current in the turn-off state when there are no nanoparticles 130 disposed in the first tunnel barrier layer 120.

As described, semiconductor devices according to embodiments of the present disclosure include a first tunnel barrier layer including a non-ferroelectric material and a second tunnel barrier layer including a ferroelectric material. In addition, the semiconductor devices include nanoparticles disposed in the first tunnel barrier layer. The nanoparticles may act as trap sites that perform trapping and de-trapping operations of electrons within the first tunnel barrier layer.

The nanoparticles as trap sites of electrons increase the tunneling current of the semiconductor device by increasing the density of the electrons passing through the first tunnel barrier layer. Accordingly, a tunneling current equal to or higher than a reference level needed for reading a signal stored in the semiconductor device is more stable and reliable, thereby improving the margin for sensing signal information of the semiconductor device. In other words, as the miniaturization of semiconductor devices progresses, embodiments of the disclosure can resolve the difficulty in securing turn-on current at a level required for sensing signal information.

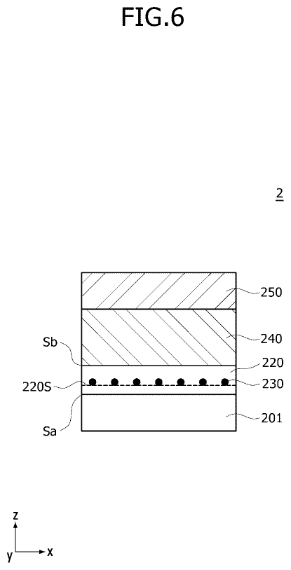

FIG. 6 is a schematic cross-sectional view illustrating a semiconductor device according to another embodiment of the present disclosure. Referring to FIG. 6, a semiconductor device 2 includes a semiconductor substrate 201, a first tunnel barrier layer 220 disposed on the semiconductor substrate 201 and including nanoparticles 230, a second tunnel barrier layer 240 disposed on the first tunnel barrier layer 220, and an electrode layer 250 disposed on the second tunnel barrier layer 240.

Referring FIG. 6, the semiconductor substrate 201 includes a semiconductor material whose electrical conductivity is controlled by an N-type or P-type dopant. The semiconductor substrate 201 performs substantially the same function as a first electrode layer 110 of a semiconductor device 1 described with reference to FIG. 1. The semiconductor material may include, for example, silicon (Si), gallium arsenide (GaAs), indium phosphide (InP), germanium (Ge), silicon germanium (SiGe), or the like.

The first tunnel barrier layer 220 may have a non-ferroelectric characteristic. The first tunnel barrier layer 220 has substantially the same configuration as a first tunnel barrier layer 120 of the semiconductor device 1 described with reference to FIG. 1.

The nanoparticles 230 are disposed in the first tunnel barrier layer 220. In an embodiment, the nanoparticles 230 are disposed in an inner region of the first tunnel barrier layer 220. The nanoparticles 230 are disposed to be spaced apart from a first interface Sa between the semiconductor substrate 201 and the first tunnel barrier layer 220 and from a second interface Sb between the first tunnel barrier layer 220 and the second tunnel barrier layer 240. In an embodiment, the nanoparticles 230 are disposed in the first tunnel barrier layer 220 and on a plane 220S spaced apart from the first interface Sa by a distance. The nanoparticles 230 have substantially the same configuration as nanoparticles 130 of the semiconductor device 1 described with reference to FIG. 1.

The second tunnel barrier layer 240 may have a ferroelectric characteristic. The second tunnel barrier layer 240 has substantially the same configuration as the second tunnel barrier layer 140 of the semiconductor device 1 described with reference to FIG. 1.

The electrode layer 250 includes a conductive material. The conductive material may include, for example, doped silicon (Si), platinum (Pt), ruthenium (Ru), iridium (Ir), tungsten (W), titanium (Ti), copper (Cu), aluminum (Al), tungsten nitride, titanium nitride, tantalum nitride, ruthenium oxide, iridium oxide, or a combination of two or more thereof. As an example, the electrode layer 250 may include metal, conductive metal nitride, conductive metal oxide, or a combination of two or more thereof, such that the semiconductor substrate 201 and the electrode layer 250 have different work functions.

In semiconductor device 2 according to an embodiment of the present disclosure, depending on a first remanent polarization orientation in the second tunnel barrier layer 240, the semiconductor substrate 201 may have an electron accumulation region in an inner region adjacent to the first tunnel barrier layer 220, and the electrode layer 250 may have an electron depletion region in an inner region adjacent to the second tunnel barrier layer 240. Alternatively, depending on a second remanent polarization orientation in the second tunnel barrier layer 240, the semiconductor substrate 201 may have an electron depletion region in an inner region adjacent to the first tunnel barrier layer 220, and the electrode layer 250 may have an electron accumulation region in an inner region adjacent to the second tunnel barrier layer 240. The first remanent polarization orientation is in the opposite direction to the second remanent polarization orientation.

As described, according to embodiments of the present disclosure, semiconductor devices may include a first tunnel barrier layer having a non-ferroelectric characteristic, a second tunnel barrier layer having a ferroelectric characteristic, and an electrode layer, which are sequentially disposed on a semiconductor substrate. Nanoparticles disposed in an inner region of the first tunnel barrier layer can increase the density of tunneling electrons passing through the first tunnel barrier layer, thereby increasing a tunneling current of the semiconductor device.

According to embodiments of the present disclosure, tunneling current equal to or higher than a reference level required for reading signal information stored in semiconductor devices can be achieved with improved stability and reliability, thereby improving the margin for sensing the signal information of the semiconductor devices. That is, it is possible to resolve the difficulty in securing a turn-on current at a level necessary for sensing the signal information, as the miniaturization of semiconductor devices progresses.

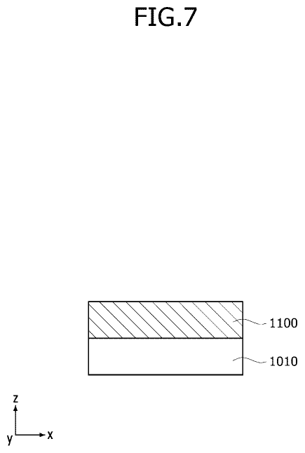

FIG. 7 to FIG. 11 are schematic cross-sectional views illustrating a method of manufacturing a semiconductor device according to an embodiment of the present disclosure. The method illustrated in FIG. 7 to FIG. 11 may be applied to a method of manufacturing a semiconductor device 1 described with reference to FIG. 1.

Referring to FIG. 7, a substrate 1010 is provided. The substrate 1010 is formed of various materials on which a semiconductor integration process may be performed. The substrate 1010 may be, for example, a semiconductor substrate, an insulating substrate, or a conductive substrate. The substrate 1010 may be, for example, a silicon (Si) substrate, a gallium arsenide (GaAs) substrate, an indium phosphide (InP) substrate, a germanium (Ge) substrate, a silicon germanium (SiGe) substrate, or a silicon-on-insulator (SOI) substrate. The substrate 1010 may be, for example, a sapphire substrate, a quartz substrate, or a glass substrate. The substrate 1010 may be, as another example, an N-type or P-type doped semiconductor substrate, or a conductive substrate.

A first electrode material layer 1100 is formed on the substrate 1010. The first electrode material layer 1100 may include, for example, doped silicon (Si), platinum (Pt), ruthenium (Ru), iridium (Ir), tungsten (W), titanium (Ti), copper (Cu), aluminum (Al), tungsten nitride, titanium nitride, tantalum nitride, ruthenium oxide, iridium oxide, or a combination of two or more thereof. The first electrode material layer 1100 may be formed using, for example, a physical vapor deposition method, a chemical vapor deposition method, an atomic layer deposition method, or the like.

In some embodiments, when the substrate 1010 is a semiconductor substrate or a conductive substrate, an interlayer insulating layer (not illustrated) may be formed between the substrate 1010 and the first electrode material layer 1100. The interlayer insulating layer may electrically insulate the substrate 1010 and the first electrode material layer 1100 from each other. The interlayer insulating layer may include oxide, nitride, or oxynitride. The interlayer insulating layer may be formed using, for example, a chemical vapor deposition method.

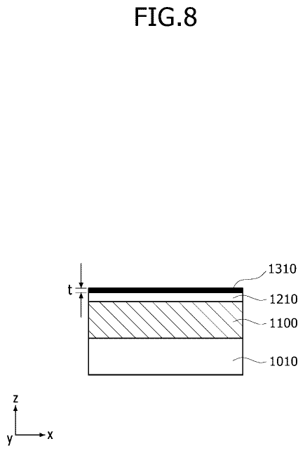

Referring to FIG. 8, a first non-ferroelectric material layer 1210 is formed on the first electrode material layer 1100. The first non-ferroelectric material layer 1210 may include a non-ferroelectric material such as silicon oxide, silicon nitride, silicon oxynitride, titanium oxide, tantalum oxide, aluminum oxide, zinc oxide, yttrium oxide, hafnium oxide, zirconium oxide, or a combination of two or more thereof. When the hafnium oxide or the zirconium oxide has a monoclinic crystal system crystal structure or a tetragonal crystal system crystal structure, the hafnium oxide or the zirconium oxide exhibit non-ferroelectricity. On the other hand, when the hafnium oxide or the zirconium oxide has an orthorhombic system crystal structure, the hafnium oxide or the zirconium oxide exhibit ferroelectricity. The first non-ferroelectric material layer 1210 may be formed using, for example, a physical vapor deposition method, a chemical vapor deposition method, an atomic layer deposition method, or the like.

A metal thin film 1310 is formed on the first non-ferroelectric material layer 1210. The metal thin film 1310 may include, for example, cobalt (Co), nickel (Ni), copper (Cu), iron (Fe), platinum (Pt), gold (Au), silver (Ag), iridium (Ir), ruthenium (Ru), palladium (Pd), manganese (Mn), or a combination of two or more thereof.

The metal thin film 1310 is formed on the first non-ferroelectric material layer 1210 to have a thickness of, for example, 0.1 nm to 3 nm. The metal thin film 1310 may be formed using, for example, a chemical vapor deposition method, an atomic layer deposition method, or the like.

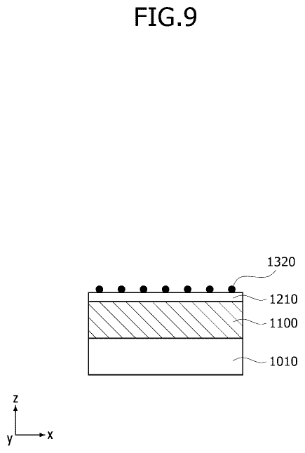

Referring to FIG. 9, self-aggregation is induced for the metal thin film 1310 formed on the first non-ferroelectric material layer 1210 to form a plurality of metal particles 1320. In an embodiment, the self-aggregation for the metal thin film 1310 may be induced by forming the metal thin film 1310 having a thickness of 0.1 nm to 3 nm, as described with reference to FIG. 8. That is, when the metal thin film 1310 having the thin thickness is formed, the metal thin film 1310 may aggregate into the metal particles 1320 to reduce surface energy. Alternatively, self-aggregation of the metal thin film 1310 may be caused by performing a subsequent process, such as heat treatment, after forming the metal thin film 1310 as described with reference to FIG. 8. The heat treatment may induce the metal thin film 1310 to self-aggregate into metal particles 1320 to lower surface energy.

Referring to FIG. 9, the metal particles 1320 may have forms in which metal atoms are aggregated. The metal particles 1320 may have a spherical or substantially spherical shape. However, shapes of the metal particles 1320 are not necessarily limited to a spherical shape, and other three-dimensional shapes are also possible. The metal particles 1320 are distributed on the first non-ferroelectric material layer 1210. In an embodiment, a metal particle 1320 having a spherical shape may have a diameter of, for example, 0.1 nm to 5 nm. Through the described methods, nanoparticles may be distributed on the first non-ferroelectric material layer 1210.

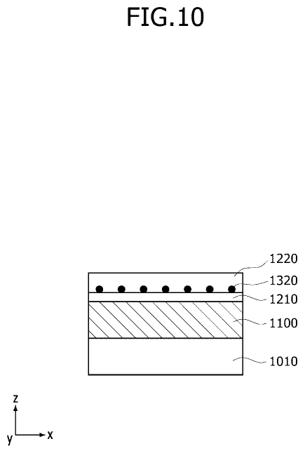

Referring to FIG. 10, a second non-ferroelectric material layer 1220 is formed on the first non-ferroelectric material layer 1210 to cover the metal particles 1320. The second non-ferroelectric material layer 1220 may include a dielectric material having non-ferroelectricity. The second non-ferroelectric material layer 1220 may include, for example, oxide, nitride, oxynitride, or a combination of two or more thereof. In an embodiment, the second non-ferroelectric material layer 1220 may be formed in a manner that buries the metal particles 1320 using substantially the same material as the first non-ferroelectric material layer 1210. The second non-ferroelectric material layer 1220 may be formed by using, for example, a chemical vapor deposition method, an atomic layer deposition method, or the like.

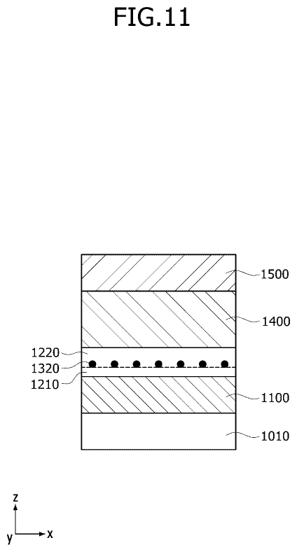

Referring to FIG. 11, a ferroelectric material layer 1400 is formed on the second non-ferroelectric material layer 1220. The ferroelectric material layer 1400 may include, for example, metal oxide having a crystal structure of an orthorhombic system. The ferroelectric material layer 1400 may include, for example, hafnium oxide, zirconium oxide, hafnium zirconium oxide, or a combination of two or more thereof.

In an embodiment, a process of doping a dopant into the ferroelectric material layer 1400 may be additionally performed. The dopant may include, for example, carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), gadolinium (Gd), lanthanum (La), or a combination thereof. The dopant helps the ferroelectric material maintain an orthorhombic system crystal structure to stabilize the ferroelectric characteristics of the ferroelectric material layer 1400.

The ferroelectric material layer 1400 may be formed, for example, by a chemical vapor deposition method, an atomic layer deposition method, or the like. The process of doping the dopant may be performed simultaneously when forming the ferroelectric material layer 1400.

Next, a second electrode material layer 1500 is formed on the ferroelectric material layer 1400. The second electrode material layer 1500 may include, for example, doped silicon (Si), platinum (Pt), ruthenium (Ru), iridium (Ir), tungsten (W), titanium (Ti), copper (Cu), aluminum (Al), tungsten nitride, titanium nitride, tantalum nitride, ruthenium oxide, iridium oxide, or a combination of two or more thereof. The second electrode material layer 1500 may be formed using, for example, a physical vapor deposition method, a chemical vapor deposition method, an atomic layer deposition method, or the like. Through the described methods, a semiconductor device according to an embodiment of the present disclosure may be manufactured.

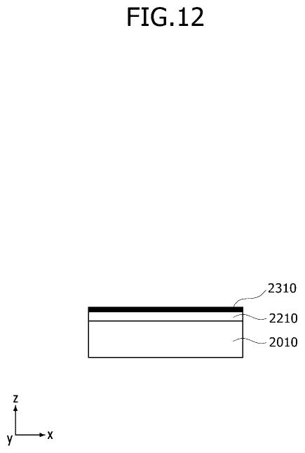

FIG. 12 to FIG. 14 are schematic cross-sectional views illustrating a method of manufacturing a semiconductor device according to another embodiment of the present disclosure. The method illustrated in FIG. 12 to FIG. 14 may be applied to a method of manufacturing a semiconductor device 2 described with reference to FIG. 6.

Referring to FIG. 12, a semiconductor substrate 2010 is provided. The semiconductor substrate 2010 includes a semiconductor material whose electrical conductivity is controlled by an N-type dopant or a P-type dopant. The semiconductor material may include, for example, silicon (Si), gallium arsenide (GaAs), indium phosphide (InP), germanium (Ge), silicon germanium (SiGe), or the like.

A first non-ferroelectric material layer 2210 is formed on the semiconductor substrate 2010. A configuration of the first non-ferroelectric material layer 2210 is substantially the same as the configuration of the first non-ferroelectric material layer 1210 described with reference to FIG. 8. The first non-ferroelectric material layer 2210 may be formed using, for example, a physical vapor deposition method, a chemical vapor deposition method, an atomic layer deposition method, or the like.

A metal thin film 2310 is formed on the first non-ferroelectric material layer 2210. The metal thin film 2310 is substantially the same as the metal thin film 1310 described with reference to FIG. 8. The metal thin film 2310 may be formed using, for example, a chemical vapor deposition method, an atomic layer deposition method, or the like.

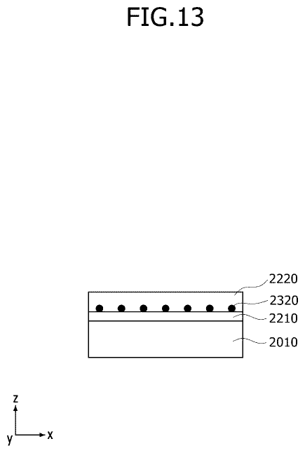

Referring to FIG. 13, self-aggregation is induced for the metal thin film 2310 formed on the first non-ferroelectric material layer 2210 to form a plurality of metal particles 2320. In an embodiment, self-aggregation of the metal thin film 2310 may occur simultaneously with the formation of the metal thin film 2310 as described with reference to FIG. 12. Alternatively, self-aggregation of the metal thin film 2310 may occur by performing a subsequent process, such as a heat treatment after forming the metal thin film 2310 as described with reference to FIG. 12.

A second non-ferroelectric material layer 2220 is formed on the first non-ferroelectric material layer 2210 to cover the metal particles 2320. A configuration of the second non-ferroelectric material layer 2220 may be substantially the same as the configuration of the second non-ferroelectric material layer 1220 described with reference to FIG. 11. The second non-ferroelectric material layer 2220 may be formed using, for example, a chemical vapor deposition method, an atomic layer deposition method, or the like.

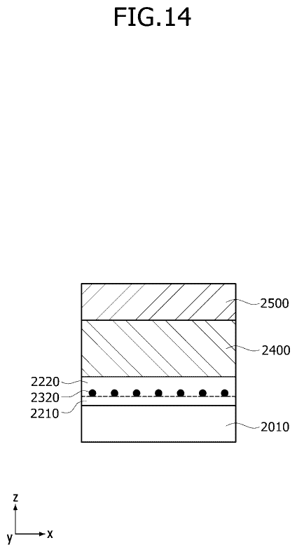

Referring to FIG. 14, a ferroelectric material layer 2400 is formed on the second non-ferroelectric material layer 2220. A configuration of the ferroelectric material layer 2400 is substantially the same as the configuration of the ferroelectric material layer 1400 described with reference to FIG. 11. The ferroelectric material layer 2400 may be formed using, for example, a chemical vapor deposition method, an atomic layer deposition method, or the like. In an embodiment, a process of doping a dopant into the ferroelectric material layer 2400 may be additionally performed. The process of doping the dopant may be substantially the same as the process of doping the ferroelectric material layer 1400 with a dopant described with reference to FIG. 11.

An electrode material layer 2500 is formed on the ferroelectric material layer 2400. A configuration of the electrode material layer 2500 may be substantially the same as the configuration of the second electrode material layer 1500 described with reference to FIG. 11. The electrode material layer 2500 may be formed using, for example, a physical vapor deposition method, a chemical vapor deposition method, an atomic layer deposition method, or the like. Through the described methods, a semiconductor device according to an embodiment of the present disclosure can be manufactured.

As described, semiconductor devices according to various embodiments of the present disclosure include a first tunnel barrier layer having a non-ferroelectric characteristic and a second tunnel barrier layer having a ferroelectric characteristic. The tunnel barrier layers are disposed between a pair of electrode layers or between an electrode layer and a substrate. Nanoparticles disposed in an inner region of the first tunnel barrier layer may increase the density of electrons passing through the first tunnel barrier layer, thereby increasing the tunneling current of the semiconductor device. Accordingly, it is possible to effectively secure a tunneling current equal to or higher than a reference level required for reading signal information stored in the semiconductor device, thereby improving a sensing margin of signal information of the semiconductor device. That is, it is possible to overcome the difficulty in securing a turn-on current at a level required for sensing the signal information as the miniaturization of the semiconductor device progresses.

In some embodiments, the semiconductor devices may be used with a memory cell of a nonvolatile memory device capable of random access. As an example, a semiconductor device may include a memory cell of a cross-point array device. Alternatively, a semiconductor device may be connected in series with a selection element such as a diode or a transistor to form one memory cell.

In some embodiments, the semiconductor device may be configured such that the second tunnel barrier layer has at least three or more remanent polarization states by using polarization hysteresis characteristics of a ferroelectric material. Here, the nanoparticles disposed in an inner region of the first tunnel barrier layer may increase the tunneling current corresponding to each of the at least three or more remanent polarization states. In this way, the semiconductor device stores and reads out at least three or more pieces of signal information, so that the semiconductor device can be applied to analog computing in memory. As an example, the semiconductor device may be used with a cell of a cell array device that stores continuous weights and performs vector matrix multiplication. That is, the semiconductor device may be applied as a memristor-based synaptic element in neuromorphic technology.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not considered from a restrictive standpoint. The scope of the present disclosure is not limited to the descriptions, and all distinctive features within an equivalent scope should be construed as included in the present disclosure. All changes within the meaning and range of equivalency of the claims are included within their scope.

What is claimed is:

1. A semiconductor device comprising:
a first electrode layer;
a first tunnel barrier layer including a non-ferroelectric material and disposed on the first electrode layer;
nanoparticles disposed in the first tunnel barrier layer;
a second tunnel barrier layer including a ferroelectric material and disposed on the first tunnel barrier layer; and
a second electrode layer disposed on the second tunnel barrier layer.

2. The semiconductor device of claim 1, wherein the nanoparticles are spaced apart from a first interface between the first electrode layer and the first tunnel barrier layer and are spaced apart from a second interface between the first tunnel barrier layer and the second tunnel barrier layer.

3. The semiconductor device of claim 2, wherein the nanoparticles are disposed on a plane spaced at a distance from and parallel to the first interface.

4. The semiconductor device of claim 1, wherein each of the nanoparticles has a diameter of 0.1 nm to 5 nm.

5. The semiconductor device of claim 1, wherein each of the nanoparticles includes at least one selected from the group consisting of cobalt (Co), nickel (Ni), copper (Cu), iron (Fe), platinum (Pt), gold (Au), silver (Ag), iridium (Ir), ruthenium (Ru), palladium (Pd), and manganese (Mn).

6. The semiconductor device of claim 1, wherein the ferroelectric material includes at least one selected from the group consisting of hafnium oxide, zirconium oxide, and hafnium zirconium oxide.

7. The semiconductor device of claim 1,
wherein the second tunnel barrier layer further includes a dopant that is doped into the ferroelectric material, and
wherein the dopant includes at least one selected from the group consisting of carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), zirconium (Zr), gadolinium (Gd), and lanthanum (La).

8. The semiconductor device of claim 1, wherein the non-ferroelectric material includes at least one selected from the group consisting of silicon oxide, silicon nitride, silicon oxynitride, titanium oxide, tantalum oxide, aluminum oxide, zinc oxide, yttrium oxide, hafnium oxide, and zirconium oxide.

9. The semiconductor device of claim 1, wherein the nanoparticles trap and de-trap electrons tunneling through the first tunnel barrier layer.

10. The semiconductor device of claim 1,
wherein the second tunnel barrier layer exhibits a remanent polarization orientation,
the first electrode layer has an electron accumulation region in an inner region adjacent to the first tunnel barrier layer, and the second electrode layer has an electron depletion region in an inner region adjacent to the second tunnel barrier layer, or the first electrode layer has an electron depletion region in the inner region adjacent to the first tunnel barrier layer, and the second electrode layer has an electron accumulation region in the inner region adjacent to the second tunnel barrier layer.

11. The semiconductor device of claim 1, wherein each of the first electrode layer and the second electrode layer includes at least one selected from the group consisting of doped silicon (Si), platinum (Pt), ruthenium (Ru), iridium (Ir), tungsten (W), titanium (Ti), copper (Cu), aluminum (Al), tungsten nitride, titanium nitride, tantalum nitride, ruthenium oxide, and iridium oxide.

12. A semiconductor device comprising:
a semiconductor substrate;
a first tunnel barrier layer disposed on the semiconductor substrate and including a non-ferroelectric material;
nanoparticles disposed in an inner region of the first tunnel barrier layer;
a second tunnel barrier layer disposed on the first tunnel barrier layer and including a ferroelectric material; and
an electrode layer disposed on the second tunnel barrier layer.

13. The semiconductor device of claim 12, wherein the nanoparticles are spaced apart from a first interface between the semiconductor substrate and the first tunnel barrier layer and are spaced apart from a second interface between the first tunnel barrier layer and the second tunnel barrier layer.

14. The semiconductor device of claim 12, wherein the nanoparticles are disposed on a plane spaced at a distance from and parallel to a first interface between the semiconductor substrate and the first tunnel barrier layer.

15. The semiconductor device of claim 12, wherein the nanoparticles trap and de-trap electrons tunneling through the first tunnel barrier layer.

16. A method of manufacturing a semiconductor device, the method comprising:
providing a substrate;
forming a first non-ferroelectric material layer on the substrate;
disposing nanoparticles on the first non-ferroelectric material layer;
forming a second non-ferroelectric material layer on the first non-ferroelectric material layer to cover the nanoparticles;
forming a ferroelectric material layer on the second non-ferroelectric material layer; and
forming an electrode material layer on the ferroelectric material layer.

17. The method of claim 16, wherein the first non-ferroelectric material layer includes at least one selected from the group consisting of silicon oxide, silicon nitride, silicon oxynitride, titanium oxide, tantalum oxide, aluminum oxide, zinc oxide, yttrium oxide, hafnium oxide, and zirconium oxide.

18. The method of claim 16, wherein disposing the nanoparticles on the first non-ferroelectric material layer includes:
forming a metal thin film having a thickness of 0.1 nm to 3 nm on the first non-ferroelectric material layer; and
inducing the metal thin film to self-aggregate to form a plurality of metal particles having a size of 0.1 nm to 5 nm.

19. The method of claim 18, wherein the metal thin film includes at least one selected from the group consisting of cobalt (Co), nickel (Ni), copper (Cu), iron (Fe), platinum (Pt), gold (Au), silver (Ag), iridium (Ir), ruthenium (Ru), palladium (Pd), and manganese (Mn).

20. The method of claim 16, wherein forming the second non-ferroelectric material layer includes the same material as the first non-ferroelectric material layer and is disposed to bury the nanoparticles.

21. The method of claim 16,
wherein the ferroelectric material layer includes metal oxide having a crystal structure of orthorhombic crystal system and a dopant doped into the metal oxide,
wherein the metal oxide includes at least one selected from the group consisting of hafnium oxide, zirconium oxide, and hafnium zirconium oxide, and
wherein the dopant includes at least one selected from the group consisting of carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), zirconium (Zr), gadolinium (Gd), and lanthanum (La).

22. The method of claim 16, further comprising forming an electrode layer between the substrate and the first non-ferroelectric material layer.
